(19) United States
(12) Patent Application Publication
(10) Pub. No.: US 2025/0191937 A1
(43) Pub. Date: Jun. 12, 2025

(54) REDRESSING A CHIP SITE ON A MULTI-CHIP LAMINATE PACKAGE

(71) Applicant: INTERNATIONAL BUSINESS MACHINES CORPORATION, ARMONK, NY (US)

(72) Inventors: Mukta Ghate Farooq, Hopewell Jct, NY (US); Aakrati Jain, Albany, NY (US); Sathyanarayanan Raghavan, Ballston Lake, NY (US); Prabudhya Roy Chowdhury, Albany, NY (US)

(21) Appl. No.: 18/537,782

(22) Filed: Dec. 12, 2023

(51) Int. Cl. H01L 21/48; H01L 23/00

(52) U.S. Cl. CPC H01L 21/4864; H01L 24/98; H01L 2224/98

(57) ABSTRACT

A method and apparatus extracts solder from a redress site of multiple chips on a laminate structure. The method includes depositing conductive pads on a flexible insulating film with a same pitch as solder bumps on a laminate structure that are to be extracted. The flexible film is mounted on a retaining surface, and the conductive pads are heated at a temperature above a solder melting temperature. The retaining surface descends toward a laminate having solder thereon until the heated conductive pads come into contact with at least one solder bump. The retaining surface is retracted from contact and includes most of the at least one contacted solder bump that was on the laminate structure. The operations repeat until the solder remaining on die pads on the laminate is similar to an amount of initially arranged pre-solder.

### BACKGROUND

### Technical Field

The present disclosure is generally related to structures with multiple chips, and more particularly, to redressing solder in such structures.

### Description of the Related Art

With the increased miniaturization of electronic components, a laminate multi-layer structure is often used for packaging multiple chips of a device. Such laminate structures are used to interconnect multiple semiconductors by various techniques including but not limited to a plastic ball grid array (PBGA), a plastic pin grid array (PPGA), a plastic land grid array (PLGA), or a chip scaled package (CSP), etc. However, when a malfunctioning/failed chip is extracted from a laminate structure, the solder used to connect a chip to the laminate needs to be redressed. There is sometimes a challenge in removing the malfunctioning/failed chip, redressing the chip site including the solder, and reattaching the new chip to the laminate so that the electrical connections are sound.

### SUMMARY

According to an embodiment, a method and apparatus extracts solder from a redress site of multiple chips on a laminate package. The method includes depositing conductive pads on a flexible film with a same pitch as solder bumps on a laminate structure to be extracted. The flexible film is retained by a surface of a die bond holder, and the conductive pads are heated at a temperature above a solder melting temperature. The flexible film is moved toward a laminate having solder thereon until the heated conductive pads come into contact with at least one solder bump on the laminate structure. The flexible film is retracted from contact and includes most of the at least one contacted solder bump that was on the laminate. The operation is repeated until the solder remaining on the laminate is similar to an amount of pre-solder initially arranged on the laminate pads.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is a plan view of a laminate structure with multiple chips arranged thereon, consistent with an illustrative embodiment.

FIG. 2 illustrates a laminate structure that is undergoing redressing, consistent with an illustrative embodiment.

FIG. 3A illustrates a laminate die pad with residual solder and a conductive pad, consistent with an illustrative embodiment.

FIG. 3B illustrates a laminate die pad with residual solder and a conductive pad that is larger than the conductor pad shown in FIG. 3A, consistent with an illustrative embodiment.

FIGS. 4A, 4B and 4C show a process flow for redressing a laminate structure consistent with an illustrative embodiment, in which FIG. 4A shows the film and conductive pads aligned above a laminate that needs redressing, FIG. 4B shows a holder retaining the film after the holder was lowered so that the conductive pad made conduct with at least one solder bump on the laminate, and FIG. 4C shows the holder retracted after a solder bump has been removed after contacted with a heated conductive pad, consistent with an illustrative embodiment.

FIG. 5 is a flowchart illustrating a process for redressing a chip site in a multichip laminate package, consistent with an illustrated embodiment.

FIG. 6 illustrates a block diagram of a computing environment of a die bonding tool configured to redress a chip site in a multichip laminate package, consistent with an illustrative embodiment.

### DETAILED DESCRIPTION

In the following detailed description, numerous specific details are set forth by way of examples to provide a thorough understanding of the relevant teachings. However, it is to be understood that the present teachings may be practiced without such details. In other instances, well-known methods, procedures, components, and/or circuitry have been described at a relatively high-level, without detail, to avoid unnecessarily obscuring aspects of the present teachings. It is also to be understood that the present disclosure is not limited to the depictions in the drawings, as there may be fewer elements or more elements than shown and described.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

As used herein, the term “chiplets” refers to a type of integration in which multiple dies are integrated in a package or system. While there are a number of variations to using chiplets, wherein the general approach is that you have a plurality of modular chips, or chiplets, in a library. The chiplets are assembled in a package and connected using a die-to-die interconnect scheme.

As used herein, a die bonder is a tool for attaching a die to another die or a substrate. A bond head typically holds a die and bonds the die to a substrate or a laminate. A die bond head, which is also referred to as a “holder” typically uses a compressive force to attach a die to a substrate. It is to be understood that the appended claims are not limited to a particular type of holder for the die. In some illustrative embodiments, a retaining surface on which the insulating film is mounted is a Thermal Conduction Bonding (TCB) too head that is used to redress the solder. However, it is to be understood that the appended claims are not limited to the use of a TCB tool head for removing/attaching operations.

A flexible film constructed of a polyimide such as Kapton® poly (4,4′-oxydiphenylene-pyromellitimide) may be used with a substrate pad to remove a solder bump from a site being redressed. Kapton® has a wide range of thermal stability (−269 to +400° C.) and electrical insulation properties. However, substances such as Nomex® poly (m-phenylenediamine isophthalamide), and Teflon® polytetrafluoroethylene (PTFE) may serve as possible substitutes.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

### TECHNICAL ADVANTAGES AND SUPPORT

It is to be understood that some of the advantages of the present disclosure are provided herein below. However, a person of ordinary skill in the art will appreciate that additional advantages may exist in addition to those described herein.

In an embodiment, a method of redressing a multi-chip laminate structure includes depositing conductive pads on a flexible insulating film, and mounting the flexible insulating film on a retaining surface. The retaining surface is heated to a temperature above a solder melting temperature. The retaining surface is descended toward the laminate structure until at least one of the conductive pads mounted on the flexible insulating film comes into contact with one or more solder bumps on the laminate solder. The retaining surface is retracted from the laminate structure when one or more of the solder bumps has melted and at least partially transferred onto the conductive pads of the retaining surface. This method provides an efficient removal of solder bumps used for multiple chips on a laminate structure so that the laminate structure can be reused (rather than discarded) after a chip is repaired or replaced.

In an embodiment, which may be combined with the preceding embodiment, the method further includes aligning the flexible insulating film with a same pitch as the one or more solder bumps to be extracted. The alignment provides for a more accurate desoldering of the solder bump so that more solder can be transferred away from the laminate structure being redressed.

In one embodiment, which can be combined with one or more preceding embodiments, the retaining surface in the descending and retracting operations is a Thermal Compression Bonding (TCB) tool head. A TCB tool head may be used to attach/remove a chip on the laminate structure is effective for use with solder bumps.

In one embodiment, which can be combined with one or more preceding embodiments, the method includes repeating the descending and retracting of the retaining surface until a residual solder amount remains on a plurality of die pads on the laminate structure on which the one or more solder bumps were previously attached. The iterative process effectively removes the solder bumps from all of the areas of the laminate structure on which a chip is being repaired or replaced, leaving a residual amount of solder as a landing pad for new solder when another chip is installed

In one embodiment, which can be combined with one or more preceding embodiments, the method includes spatially varying a pitch of the conductive pads on the flexible insulating film to align with the pitch of the one or more solder bumps. Spatial variance of the pitch provides for a more efficient transfer of the solder bumps that are to be removed from the laminate structure.

In one embodiment, which can be combined with one or more preceding embodiments, the method includes controlling a volume of the solder bumps transferred onto the conductive pads based on a size of the conductive pads used. Different size conductive pads mounted onto the flexible insulating film can control the amount of solder removed from the laminate structure being redressed.

In one embodiment, which can be combined with one or more preceding embodiments, the method includes detecting whether the conductive pads on the flexible insulating film are in contact with the one or more solder bumps by a force feedback of the retaining surface. Through the use of a sensor, contact can be ensured but excessive force is prevented from being applied to the laminate structure being redressed.

In one embodiment, which can be combined with one or more preceding embodiments, the method includes that the mounting of the flexible insulating film on a retaining surface includes applying a vacuum. The vacuum can help to retain the flexible insulating film and to remove debris from the laminate structure being redressed.

In one embodiment, which can be combined with one or more preceding embodiments, the method includes sweeping one or more die pads on the laminate structure having residual solder after the one or more solder bumps has partially transferred to the conductive pads. The sweeping may occur after each pass or periodically, such as after every other pass, etc. The operations keep the laminate free of debris.

In one embodiment, which can be combined with one or more preceding embodiments, the method includes mechanically separating at least one chip from the laminate structure prior to redressing the laminate structure. Initially, in a laminated structure having multiple chips, a failing or degraded chip must be removed prior to the redressing. A mechanical separation is preferred to remove the chip from the laminate, then the laminate structure can be redressed.

In an embodiment, a device that redresses a multichip laminate structure, the computer-controlled device includes a processor, and a storage device coupled to the processor. The storage device stores instructions to cause the processor to perform acts including depositing conductive pads on a flexible insulating film; mounting the flexible insulating film on a retaining surface; heating the retaining surface to a temperature above a solder melting temperature; descending the retaining surface toward the laminate site until at least one of the conductive pads mounted on the flexible insulating film comes into contact with one or more solder bumps on the laminate solder; and retracting the retaining surface when one or more of the solder bumps has melted and at least partially transferred onto the conductive pads of the flexible insulating film. This device provides an efficient removal of solder bumps used for the heterogenous integration of chips from a laminate structure so that the laminate structure can be reused (rather than discarded) after a chip is repaired or replaced.

In an embodiment, which may be combined with the preceding embodiment, the flexible insulating film is a polyimide structure. Polyimide structures provide a large range of temperature insulation and electrical insulation

In one embodiment, which can be combined with one or more preceding embodiments, the polyamide structure is a Kapton® film. This particular film is used to mount conductive pads onto a TCB head.

In one embodiment, which can be combined with one or more preceding embodiments, the conductive pads are copper pads. Copper is particularly efficient for use in a conductive pad to desolder a solder bump(s) when a laminate structure is being redressed.

In one embodiment, which can be combined with one or more preceding embodiments, the instructions cause the processor to perform an additional act of aaligning the flexible insulating film with a same pitch as the one or more solder bumps to be extracted. The alignment provides for a more accurate desoldering of the solder bump so that more solder can be transferred away from the laminate structure being redressed.

In one embodiment, which can be combined with one or more preceding embodiments, the instructions cause the processor to perform additional acts of repeating the descending of the retaining surface until contact is made between at least one of the conductive pads and the one or more solder bumps and retracting the retaining surface when one or more of the solder bumps has melted. The iterative operations effectively remove the solder bumps from all of the areas of the laminate structure on which a chip is being repaired or replaced, leaving a residual amount of solder as a landing pad for new solder when another chip is installed.

In one embodiment, which can be combined with one or more preceding embodiments, the instructions cause the processor to perform additional acts of repeating the descending and retracting of the retaining surface until a residual solder amount remains on a plurality of die pads on the laminate structure on which the one or more solder bumps were previously attached. The iterative process effectively removes the solder bumps from all of the areas of the laminate structure on which a chip is being repaired or replaced, leaving a residual amount of solder as a landing pad for new solder when another chip is installed.

In one embodiment, which can be combined with one or more preceding embodiments, the instructions cause the processor to perform additional acts of spatially varying a pitch of the conductive pads on the flexible insulating film to align with the pitch of the one or more solder bumps. The spatial variance of the pitch provides for a more efficient desoldering of the solder bumps on the alignment structure being redressed.

In one embodiment, which can be combined with one or more preceding embodiments, a volume of solder extracted from the one or more solder bumps is based on a size of the conductive pad. The amount of solder that is desired to be removed can be controlled based on a size of the conductive pads arranged on the flexible insulating film.

### Overview

The present disclosure is generally directed to a device and a method for redressing a chip site in a multi-chip laminate package. The current technology is advancing toward arranging multiple chips (which may be multiple chips that are the same or may be different) on a laminate structure. For example, multiple chips are assembled on one laminate. The industry indicates this type of construction can be the future of microelectronic packages. The laminate used in the arrangement of multiple chips is not a simple organic laminate because the chips need to communicate in a very large bandwidth. Therefore, the laminate is expensive to fabricate.

One of the shortcomings of multiple chips attached to a laminate is that if one of the multiple chips attached to the laminate package fails, it is too costly to discard the entire package. Thus, pulling out the failing chip and redressing the site followed by attaching a new functioning chip must be performed. The device and method set forth in the present disclosure provides an improvement in redressing the chip site.

In a laminate package, the chips are connected to each other through solder bumps. Between the chips, there is pitch and line spacing. The laminate includes a plurality of thin metal wires, and they connect to bumps via laminate pads.

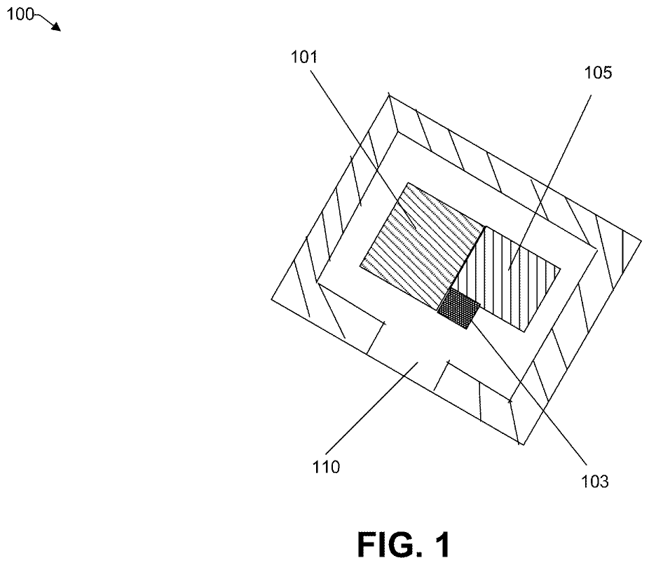

FIG. 1 is a plan view 100 of a laminate package with multiple chips arranged thereon, consistent with an illustrative embodiment. There are shown three chips 101, 103 and 105 that are bonded to a laminate 110, typically by solder bumps. The chip 105 often needs to be removed and either repaired or replaced because heterogenous integrated structures such as shown in FIG. 1 are too expensive to discard because of a single chip failure. The chip 105 may be physically separated from the laminate with a tool such as a die bond holder tool. Once the chip 105 is removed from the laminate, the method to redress the laminate begins so that a repaired or new chip may be attached to the laminate in place of the chip 105 that was removed.

The method includes depositing conductive pads on a flexible thermally-insulating film. The flexible thermally-insulating film (with the conductive pads) is mounted on a retaining surface, and the conductive pads are heated above the solder melting temperature. The retaining surface is retracted and the operations are repeated until the residual solder left on the laminate pad is an amount similar to a pre-solder amount that were on the laminate pads prior to bonding. A wiper (e.g., a squeegee) may be used to clean the residual solder on the laminate pad each time the tool head assembly is raised, or at periodic intervals.

### Example Embodiment(s)

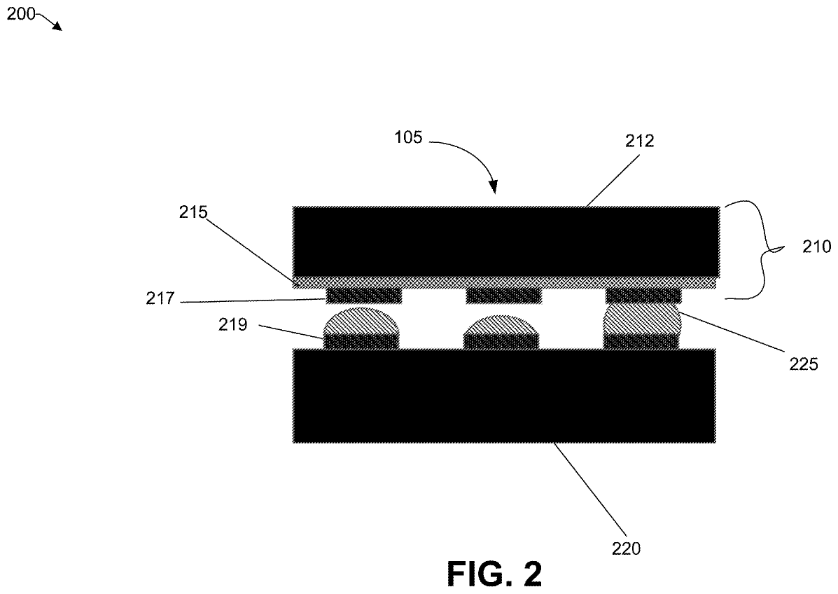

FIG. 2 is a front view 200 of a laminate structure that is undergoing redressing, consistent with an illustrative embodiment. FIG. 2 shows the chip 105 (FIG. 1), in which a tool head assembly 210 includes a retaining surface fixture 212, an insulating flexible film 215, and conductive pads 217. The conductive pads may be a metal such as copper, but are not limited to this material, and may also be an alloy. As disclosed above, the flexible film may be Kapton® or another insulating film with high heat resistance and electrical resistance.

It is also shown in FIG. 2 that the laminate has pads 219, which may be referred to as a die pads. Solder bumps 225 are compressed between the conductive pads 217 and the laminate pads 219.

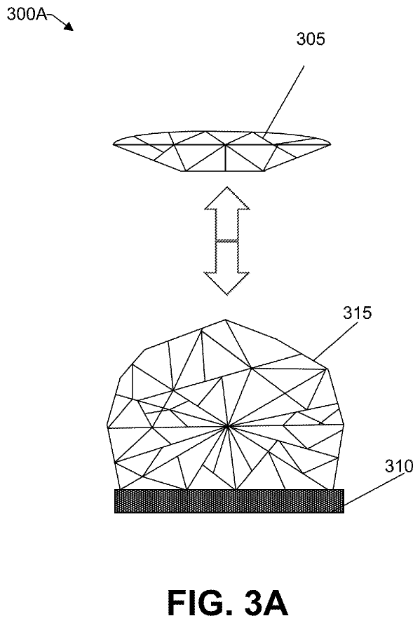

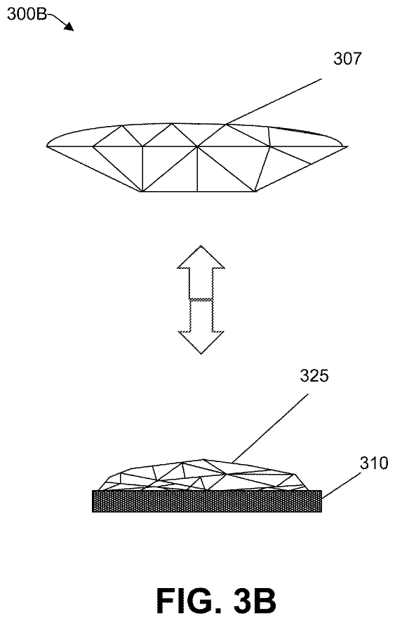

FIG. 3A is an illustration 300A of a residual solder on a laminate pad 310 with a conductive pad, consistent with an illustrative embodiment. FIG. 3B is an illustration 300B of a residual solder on a laminate pad 310 with an overhead conductive pad that is larger than the overhead conductive pad shown in FIG. 3A, consistent with an illustrative embodiment. The conductor pad 305 in FIG. 3A has a diameter that is similar to the diameter of the solder bump 315. In FIG. 3B, the conductor pad 307 is larger than the conductive pad 305 in FIG. 3A. The larger conductive pad 307, when heated, will remove more solder than the smaller conductive pad 305. After one or more contacts of the conductive pads 305, 307 (when heated) with the solder bumps 315, 325, it is shown that more solder has been removed from the solder bump 325 in FIG. 3B than the solder bump 315 in FIG. 3A. It should be understood that a cleaning operation may occur between each contact of the conductive pads and solder bumps, or at predetermined intervals. The cleaning operation may include an automated squeegee that is a part of a die bonder holder apparatus to clean the residual solder after the conductive pad 305, 307 is raised.

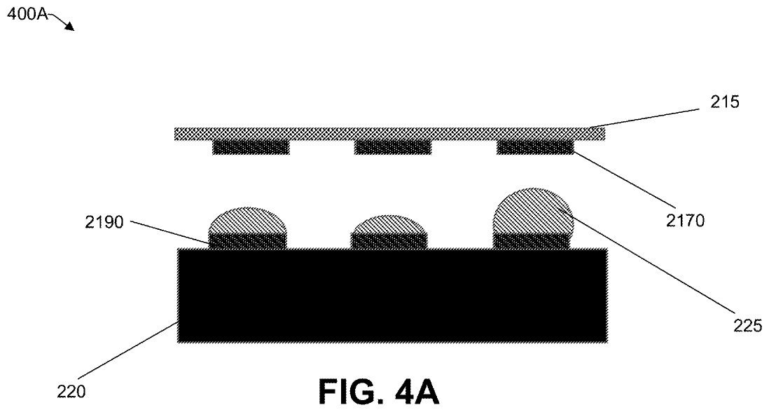

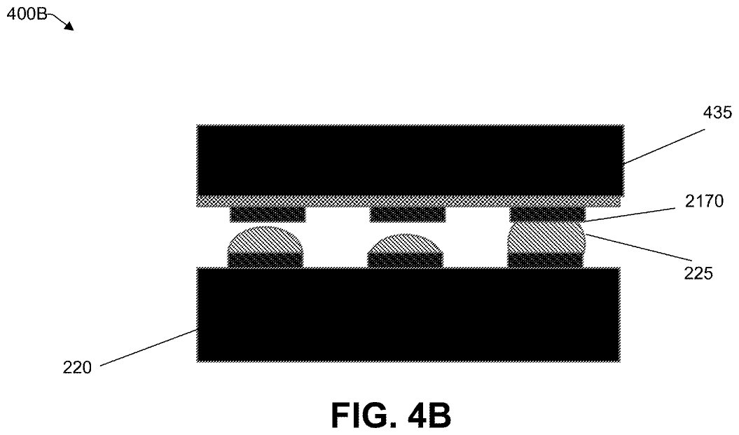

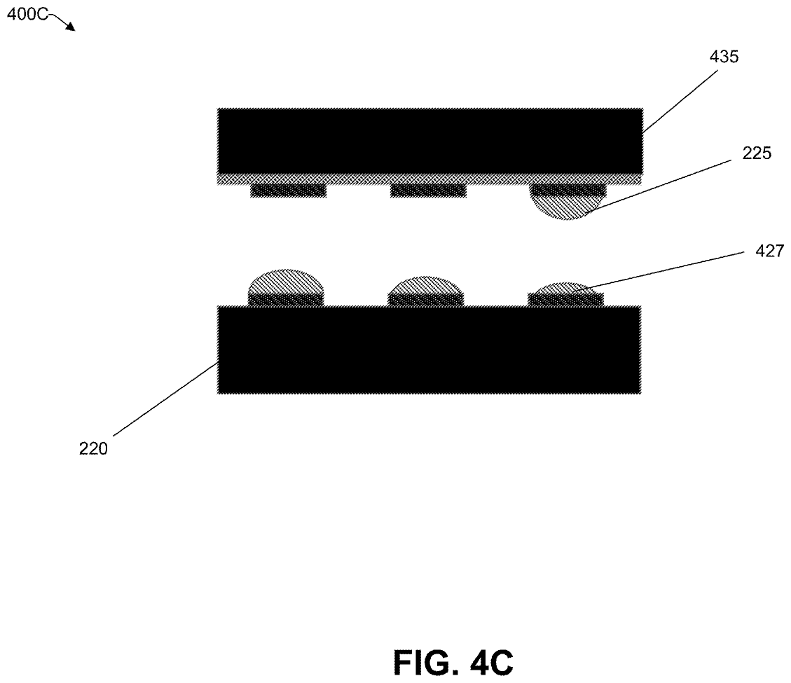

FIGS. 4A, 4B and 4C show a process flow for redressing a laminate consistent with an illustrative embodiment, in which FIG. 4A shows the film and conductive pads aligned above a laminate that needs redressing, FIG. 4B shows a retaining surface holding the film after the retaining surface was lowered so that the conductive pad made conduct with at least one solder bump on the laminate, and FIG. 4C shows the retaining surface retracted after a solder bump has been removed after contacted with a heated conductive pad, consistent with an illustrative embodiment.

Referring to FIG. 4A, there is shown a front view 400A of a laminate 220 that needs redressing. For example, there was a chip 105 (see FIG. 1) that was arranged on the laminate 220 that needed to be repaired or replaced. The conductive pads used in this illustrated embodiment are copper pads 2170, 2190. However, other types of solderphillic material may be used. To redress the laminate 220 copper pads 2170 are arranged on the film 215 having a size and pitch that is similar to the size and pitch of the solder bumps 225. The film 215 in this illustrative embodiment is a flexible conformal Kapton® film. The film 215 is mounted on a platform 435 to form a tool head assembly 210 (see FIG. 2) that is aligned above the laminate 220 and the copper pads 2170 are heated to a temperature above the melting temperature of the solder bumps 225. The mounting may include using vacuum to retain the film 215 by the platform 435. It is noted that the heating of the copper pads 2170 may alternatively be heated after contact with the solder bumps, or may be preheated to a first temperature, and then after contact with at least one solder bump 225 may be heated to a second temperature higher than the first temperature.

Referring to FIG. 4B, there is shown a front view 400B of the platform 435 being lowered until contact with the copper pads 2170 is made with at least one solder bump 225. The vacuum may be pulled (e.g., reduced or stopped) and the temperature is increased to ensure that the solder bump 225 is melted. While only one solder bump 225 is shown as being in contact with one of the copper pads 2170, there may be more than one solder bump 225 in contact with a respective copper pad 2170. As the process of lowering and retracting the platform 435 is repeated, the taller bumps will be removed and the copper pads 2170 will then contact and heat the other sold bumps 225 that may not have been in contact with a copper pad 2170 on the previous lowering(s) of the platform 435.

Referring to FIG. 4C, there is shown a front view 400C of the platform 435 after it is retracted from the laminate 220 by the tool head assembly 210 (FIG. 2). FIG. 4C shows that the solder bump 225 has mainly transferred onto the heated copper pad 2170, leaving a residual solder amount 427 on the copper pad 2190 attached to the laminate 220. It is also noted that the vacuum that was reduced or stopped may have been returned to a previous level used prior to the descent of the platform 435 to ensure that the film 215 is firmly held in place when the platform 435 with the film 215 is raised. The platform 435 and the residual solder 227 on the laminate may be cleaned by a sweeper that scraps/wipes the surfaces to remove any debris. IT is noted that not all of the solder can be removed from the copper pads 2190 on the laminate 220. The remaining solder serves as a landing pad for the solder used to subsequently attach a new or repaired chip.

### Example Process

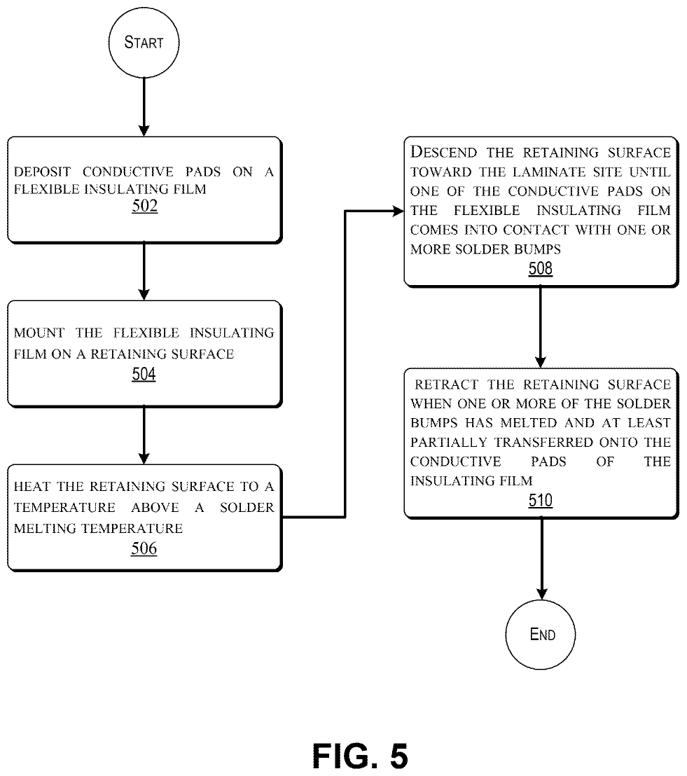

With the foregoing overview of the example architecture, it may be helpful now to consider a high-level discussion of an example process. To that end, FIG. 5 is a flowchart illustrating a process for redressing a chip site in a multichip laminate package, consistent with an illustrated embodiment.

The method begins with depositing conductive pads on a flexible insulating film (502). It is understood that one or more chips have been previously mechanically separated from the laminate structure, and now the laminate structure is being redressed so that a repaired or replacement chip may be arranged on the laminate structure. As previously disclosed herein, the flexible insulating film may be a polyimide such as Kapton®. The conductive pads in this illustrated embodiment are copper, however, any solderphillic material may be used.

The flexible insulating film including the conductive pads are mounted onto a retaining surface of a device such as a die bonding device (504).

The retaining surface is heated to a temperature above a melting temperature of the solder bumps (506). The conductive pads of the retaining surface may be heated to the desired melting temperature prior to contact with the solder bump. Alternatively, the temperature may be raised to an initial level and then increased once contact with the solder bumps is detected. The heating may also begin after the contact with the solder bumps are detected as the retaining surface is being lowered toward the laminate structure.

The retaining surface is descended toward the laminate structure until one of the conductive pads on the flexible insulating film comes into contact with one or more solder bumps (508). The contact may be determined through force feedback detected by a sensor attached to the retaining surface.

The retaining surface is retracted after the solder bump has melted (510). Most of the solder bump transfer onto the conductive pad of the retaining surface because of the heat and a vacuum that may be applied. The descending and retracting of the retaining surface may be performed until all of the solder bumps have been removed such that only a residual amount of solder approximate to a presolder amount on the die pads on the laminate is left to serve as a landing pad for the solder to be used to attached the replacement or repaired chip.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

### Computing Environment

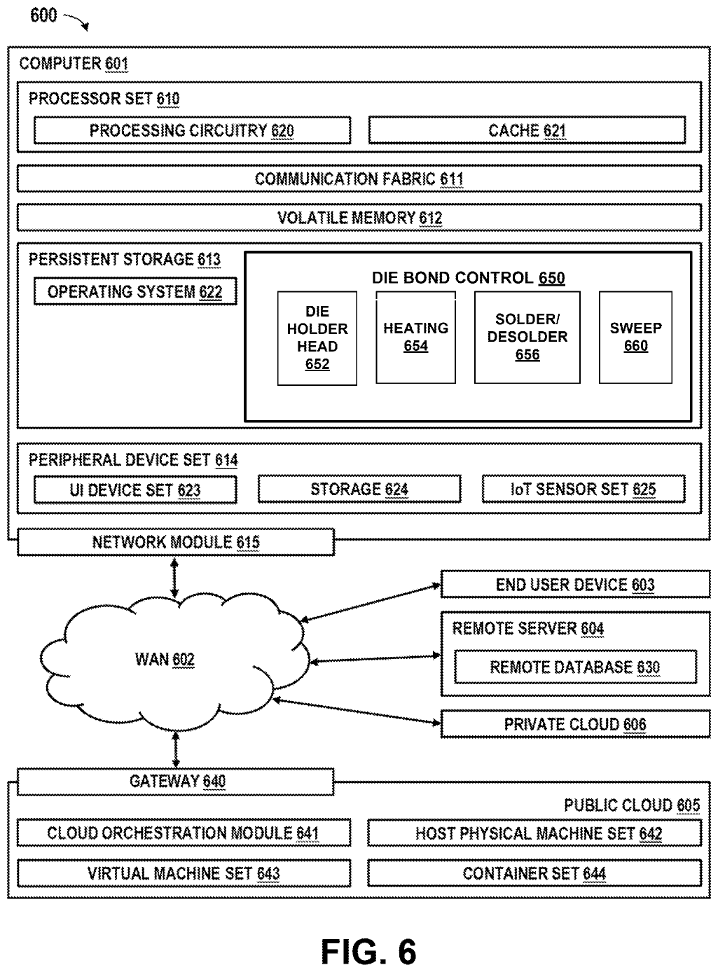

FIG. 6 illustrates a block diagram of a computing environment of a die bonding tool configured to redress a chip site in a multichip laminate package, consistent with an illustrative embodiment.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: hard diskette, disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

With reference to FIG. 6, the computing environment 600 includes an example of an environment for the execution of at least some of the computer code involved in performing the inventive methods. In an embodiment, computer executable instructions in a die bond control module 650 that monitors and controls the various components of a die bonding device. For example, the die holder head control 652 picks up and/or releases a semiconductor die during a redressing operation. In an embodiment, there may be a vacuum applied to retain the die to the die head. The heating element model 654 controls a heating of the solder that is to be removed during a redress operation. The soldering/desoldering module 656 controls removal of the solder from a pad similar to an amount of presolder present before the die being held by the die head was assembled onto a laminate pad. The sweep control 658 controls a wiper or squeegee to clean the laminate pad of residual solder debris that may be present after the desoldering operation.

In addition, computing environment 600 includes, for example, computer 601, wide area network 602 (WAN), end user device 603 (EUD), remote server 604, public cloud 605, and private cloud 606. In this embodiment, computer 601 includes processor set 610 (including processing circuitry 620 and cache 621), communication fabric 611, volatile memory 612, persistent storage 613 (including operating system 622 and die bond control module 650, as identified above), peripheral device set 614 (including user interface (UI) device set 623, storage 624, and Internet of Things (IoT) sensor set 625), and network module 665. Remote server 604 includes remote database 560. Public cloud 605 includes gateway 640, cloud orchestration module 641, host physical machine set 642, virtual machine set 643, and container set 644.

Computer 601 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 630. As is well understood in the art of computer technology, and depending upon the technology, performance of a computer-implemented method may be distributed among multiple computers and/or between multiple locations. On the other hand, in this presentation of computing environment 600, detailed discussion is focused on a single computer, specifically Computer 601, to keep the presentation as simple as possible. Computer 601 may be located in a cloud, even though it is not shown in a cloud in FIG. 6. On the other hand, Computer 601 is not required to be in a cloud except to any extent as may be affirmatively indicated.

Processor set 610 includes one, or more, computer processors of any type now known or to be developed in the future. Processing circuitry 620 may be distributed over multiple packages, for example, multiple, coordinated integrated circuit chips. Processing circuitry 620 may implement multiple processor threads and/or multiple processor cores. Cache 621 is memory that is located in the processor chip package(s) and is typically used for data or code that should be available for rapid access by the threads or cores running on processor set 610. Cache memories are typically organized into multiple levels depending upon relative proximity to the processing circuitry. Alternatively, some, or all, of the cache for the processor set may be located “off chip.” In some computing environments, processor set 610 may be designed for working with qubits and performing quantum computing.

Computer readable program instructions are typically loaded onto Computer 601 to cause a series of operational steps to be performed by processor set 610 of Computer 601 and thereby effect a computer-implemented method, such that the instructions thus executed instantiates the methods specified in flowcharts and/or narrative descriptions of computer-implemented methods included in this document (collectively referred to as “the inventive methods”). These computer readable program instructions are stored in various types of computer readable storage media, such as cache 621 and the other storage media discussed below. The program instructions, and associated data, are accessed by processor set 610 to control and direct performance of the inventive methods. In computing environment 600, at least some of the instructions for performing the inventive methods may be stored in persistent storage 613.

Communication fabric 611 is the signal conduction path that allows the various components of Computer 601 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 612 is any type of volatile memory now known or to be developed in the future. Examples include dynamic type random access memory (RAM) or static type RAM. Typically, volatile memory 612 is characterized by random access, but this is not required unless affirmatively indicated. In Computer 601, the volatile memory 612 is located in a single package and is internal to Computer 601, but, alternatively or additionally, the volatile memory may be distributed over multiple packages and/or located externally with respect to Computer 601.

Persistent storage 613 is any form of non-volatile storage for computers that is now known or to be developed in the future. The non-volatility of this storage means that the stored data is maintained regardless of whether power is being supplied to Computer 601 and/or directly to persistent storage 613. Persistent storage 613 may be a read only memory (ROM), but typically at least a portion of the persistent storage allows writing of data, deletion of data and re-writing of data. Some familiar forms of persistent storage include magnetic disks and solid-state storage devices. Operating system 622 may take several forms, such as various known proprietary operating systems or open-source Portable Operating System Interface-type operating systems that employ a kernel. The code included in the persistent storage 613 typically includes at least some of the computer code involved in performing the inventive methods.

Peripheral device set 614 includes the set of peripheral devices of Computer 601. Data communication connections between the peripheral devices and the other components of Computer 601 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 623 may include components such as a display screen, speaker, microphone, wearable devices (such as goggles and smart watches), keyboard, mouse, printer, touchpad, game controllers, and haptic devices. Storage 624 is external storage, such as an external hard drive, or insertable storage, such as an SD card. Storage 624 may be persistent and/or volatile. In some embodiments, storage 624 may take the form of a quantum computing storage device for storing data in the form of qubits. In embodiments where Computer 601 is required to have a large amount of storage (for example, where Computer 601 locally stores and manages a large database) then this storage may be provided by peripheral storage devices designed for storing very large amounts of data, such as a storage area network (SAN) that is shared by multiple, geographically distributed computers. IoT sensor set 625 is made up of sensors that can be used in Internet of Things applications. For example, one sensor may be a thermometer and another sensor may be a motion detector.

Network module 615 is the collection of computer software, hardware, and firmware that allows Computer 601 to communicate with other computers through WAN 602. Network module 615 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 615 are performed on the same physical hardware device. In other embodiments (for example, embodiments that utilize software-defined networking (SDN)), the control functions and the forwarding functions of network module 615 are performed on physically separate devices, such that the control functions manage several different network hardware devices. Computer readable program instructions for performing the inventive methods can typically be downloaded to Computer 601 from an external computer or external storage device through a network adapter card or network interface included in network module 615.

WAN 602 is any wide area network (for example, the internet) capable of communicating computer data over non-local distances by any technology for communicating computer data, now known or to be developed in the future. In some embodiments, the WAN 602 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 603 is any computer system that is used and controlled by an end user (for example, a customer of an enterprise that operates Computer 601) and may take any of the forms discussed above in connection with Computer 601. EUD 603 typically receives helpful and useful data from the operations of Computer 601. For example, in a hypothetical case where Computer 601 is designed to provide a recommendation to an end user, this recommendation would typically be communicated from network module 615 of Computer 601 through WAN 602 to EUD 603. In this way, EUD 603 can display, or otherwise present, the recommendation to an end user. In some embodiments, EUD 603 may be a client device, such as thin client, heavy client, mainframe computer, desktop computer and so on.

Remote server 604 is any computer system that serves at least some data and/or functionality to Computer 601. Remote server 604 may be controlled and used by the same entity that operates Computer 601. Remote server 604 represents the machine(s) that collect and store helpful and useful data for use by other computers, such as Computer 601. For example, in a hypothetical case where Computer 601 is designed and programmed to provide a recommendation based on historical data, then this historical data may be provided to Computer 601 from remote database 630 of remote server 604.

Public cloud 605 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 605 is performed by the computer hardware and/or software of cloud orchestration module 641. The computing resources provided by public cloud 605 are typically implemented by virtual computing environments that run on various computers making up the computers of host physical machine set 642, which is the universe of physical computers in and/or available to public cloud 605. The virtual computing environments (VCEs) typically take the form of virtual machines from virtual machine set 643 and/or containers from container set 644. It is understood that these VCEs may be stored as images and may be transferred among and between the various physical machine hosts, either as images or after instantiation of the VCE. Cloud orchestration module 641 manages the transfer and storage of images, deploys new instantiations of VCEs and manages active instantiations of VCE deployments. Gateway 640 is the collection of computer software, hardware, and firmware that allows public cloud 605 to communicate through WAN 602.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 606 is similar to public cloud 605, except that the computing resources are only available for use by a single enterprise. While private cloud 606 is depicted as being in communication with WAN 602, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 605 and private cloud 606 are both part of a larger hybrid cloud.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to better explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A method of redressing a multi-chip laminate structure, the method comprising:
depositing conductive pads on a flexible insulating film;
mounting the flexible insulating film on a retaining surface
heating the retaining surface to a temperature above a solder melting temperature;
descending the retaining surface with the flexible insulating film toward the laminate structure until at least one of the conductive pads mounted on the flexible insulating film comes into contact with one or more solder bumps on the laminate structure; and
retracting the retaining surface with the flexible insulating film when one or more of the solder bumps has melted and at least partially transferred onto the conductive pads of the retaining surface.

2. The method according to claim 1, further comprising aligning the flexible insulating film with a same pitch as the one or more solder bumps to be extracted.

3. The method according to claim 1, wherein the retaining surface in the descending and retracting operations is a Thermal Compression Bonding (TCB) tool head.

4. The method according to claim 1, further comprising repeating the descending and retracting of the retaining surface with the flexible insulating film until a residual solder amount remains on a plurality of die pads on the laminate structure on which the one or more solder bumps were previously attached.

5. The method according to claim 4, further comprising controlling a volume of the solder bumps transferred onto the conductive pads based on a size of the conductive pads used and wetting the conductive pads prior to extracting the solder bumps.

6. The method according to claim 1, further comprising spatially varying a pitch of the conductive pads on the flexible insulating film to align with the pitch of the one or more solder bumps.

7. The method according to claim 1, detecting the conductive pads on the flexible insulating film are in contact with the one or more solder bumps by a force feedback of the retaining surface with the insulating film.

8. The method according to claim 1, wherein the mounting of the flexible insulating film on the retaining surface includes applying a vacuum.

9. The method according to claim 1, further comprising sweeping the partially transferred solder from the conductive pads after the retaining surface with the flexible insulating film is retracted from the laminate structure.

10. The method according to claim 1, further comprising sweeping one or more die pads on the laminate structure having residual solder after the one or more solder bumps has partially transferred to the conductive pads.

11. The method according to claim 1, further comprising mechanically separating at least one chip from the laminate structure prior to redressing the laminate structure.

12. A device that redresses a multichip laminate structure, the device comprising:
a processor;
a storage device coupled to the processor;
the storage device storing instructions to cause the processor to perform acts comprising:
depositing conductive pads on a flexible insulating film;
mounting the flexible insulating film on a retaining surface;
heating retaining to a temperature above a solder melting temperature;
descending the retaining surface toward the laminate structure until at least one of the conductive pads mounted on the flexible insulating film comes into contact with one or more solder bumps on the laminate structure; and
retracting the retaining surface when one or more of the solder bumps has melted and at least partially transferred onto the conductive pads on the flexible insulating film.

13. The device according to claim 12, wherein the flexible insulating film comprises a polyimide structure.

14. The device according to claim 13, wherein the polyimide structure comprises a Kapton® film.

15. The device according to claim 12, wherein the conductive pads comprise copper pads.

16. The device according to claim 12, wherein the instructions cause the processor to perform an additional act comprising aligning the flexible insulating film with a same pitch as the one or more solder bumps to be extracted.

17. The device according to claim 12, wherein the instructions cause the processor to perform additional acts comprising repeating the descending of the retaining surface until contact is made between at least one of the conductive pads and the one or more solder bumps and retracting the retaining surface when one or more of the solder bumps has melted.

18. The device according to claim 12, wherein the retaining surface comprises a Thermal Compression Bonding (TCB) tool head, and wherein the instructions cause the processor to perform additional acts comprising repeating the descending and retracting of the TCB tool head until a residual solder amount remains on a plurality of die pads on the laminate structure on which the one or more solder bumps were previously attached.

19. The device according to claim 12, wherein the instructions cause the processor to perform additional acts comprising spatially varying a pitch of the conductive pads on the flexible insulating film to align with the pitch of the one or more solder bumps.

20. The device according to claim 12, wherein a volume of solder extracted from the one or more solder bumps based on a size of the conductive pads.
